(19) United States
(12) Patent Application Publication
(10) Pub. No.: US 2012/0161320 A1
(43) Pub. Date: Jun. 28, 2012

(54) COBALT METAL BARRIER LAYERS

(76) Inventors: Rohan N. Akolkar, Hillsboro, OR (US); James S. Clarke, Hillsboro, OR (US)

(21) Appl. No.: 12/978,175

(22) Filed: Dec. 23, 2010

(51) Int. Cl. H01L 23/532; H01L 21/768

(52) U.S. Cl. 257/751; 438/643; 257/E23.161; 257/E21.585

(57) ABSTRACT

Electrical interconnects for integrated circuits and methods of fabrication of interconnects are provided. Devices are provided comprising copper interconnects having metal liner layers comprising cobalt and a metal selected from the group consisting of Ru, Pt, Ir, Pd, Re, or Rh. Devices having barrier layers comprising ruthenium and cobalt are provided. Methods include providing a substrate having a trench or via formed therein, forming a metal layer, the metal being selected from the group consisting of Ru, Pt, Ir, Pd, Re, and Rh, onto surfaces of the feature, depositing a copper seed layer comprising a cobalt dopant, and depositing copper into the feature.

### CROSS REFERENCE TO RELATED APPLICATIONS

The present application is related to U.S. application Ser. No. 12/890,462, entitled “Barrier Layers,” filed Sep. 24, 2010.

### BACKGROUND OF THE INVENTION

1. Field of the Invention

The embodiments of the present invention relate generally to semiconductor processing, integrated circuits, barrier layers for metal interconnects, low-k dielectrics, and gapfill during deposition in semiconductor processing applications.

2. Background Information

The desire for ever-smaller integrated circuits (IC) places enormous performance demands on the materials used to construct IC devices. In general, an integrated circuit chip is also known as a microchip, a silicon chip, or a chip. IC chips are found in a variety of common devices, such as the microprocessors in computers, cars, televisions, CD players, and cellular phones. A plurality of IC chips are typically built on a silicon wafer (a thin silicon disk, having a diameter, for example of 300 mm) and after processing the wafer is diced apart to create individual chips. A 1 cm² IC chip having feature sizes around of about 90 nm can comprise hundreds of millions of components. Current technologies are pushing feature sizes even smaller than 45 nm.

### BRIEF DESCRIPTION OF THE FIGURES

FIG. 1 shows an interconnect structure for an integrated circuit chip having barrier layer between the metal interconnect and the other components (e.g., dielectric materials) that make up the integrated circuit chip.

FIGS. 2A-E demonstrate a process for forming a barrier layer useful in metal interconnect structures for integrated circuit chips.

FIG. 3 describes a process for forming a barrier layer useful in metal interconnect structures for integrated circuit chips.

### DETAILED DESCRIPTION OF THE INVENTION

Electronic connections between the electronic devices (e.g., transistors) in an integrated circuit (IC) chip are currently typically created using copper metal or alloys of copper metal. Devices in an IC chip can be placed not only across the surface of the IC chip but devices can also be stacked in a plurality of layers on the IC chip. Electrical interconnections between electronic devices that make up the IC chip are built using vias and trenches that are filled with conducting material. Layer(s) of insulating materials, frequently, low-k dielectric materials, separate the various components and devices in the IC chip.

The substrate on which the devices of the IC circuit chip are built is, for example, a silicon wafer or a silicon-on-insulator substrate. Silicon wafers are substrates that are typically used in the semiconductor processing industry, although embodiments of the invention are not dependent on the type of substrate used. The substrate could also be comprised of germanium, indium antimonide, lead telluride, indium arsenide, indium phosphide, gallium arsenide, gallium antimonide, and or other Group III-V materials either alone or in combination with silicon or silicon dioxide or other insulating materials. Devices that make up the IC chip are built on the substrate surface.

At least one dielectric layer is deposited on the substrate. Dielectric materials include, but are not limited to, silicon dioxide (SiO₂), low-k dielectrics, silicon nitrides, and or silicon oxynitrides. The dielectric layer optionally includes pores or other voids to further reduce its dielectric constant. Typically, low-k films are considered to be any film with a dielectric constant smaller than that of SiO₂ which has a dielectric constant of about 4.0. Low-k films having dielectric constants of about 3 to about 2.7 are typical of current semiconductor fabrication processes. The production of integrated circuit device structures often also includes placing a silicon dioxide (SiO₂) film or layer, or capping layer on the surface of low-k (low dielectric constant) ILD (inter-layer dielectric) films. Low-k films can be, for example, boron, phosphorous, or carbon doped silicon oxides. Carbon-doped silicon oxides can also be referred to as carbon-doped oxides (CDOs) and organo-silicate glasses (OSGs).

To form electrical interconnects, dielectric layers are patterned to create one or more trenches and or vias within which metal interconnects are formed. The terms trenches and vias are used herein because these are the terms commonly associated with the features that are used to form metal interconnects. In general, a feature used to form a metal interconnect is a depression having any shape formed in a substrate or layer deposited on the substrate. The feature is filled with conducting interconnect material. The trenches and or vias may be patterned (created) using conventional wet or dry etch semiconductor processing techniques. Dielectric materials are used to electrically isolate metal interconnects from the surrounding components. Barrier layers are used between the metal interconnects and the dielectric materials to prevent metal (such as copper) migration into the surrounding materials. Device failure can occur, for example, in situations in which copper metal is in contact with dielectric materials because the copper metal can ionize and penetrate into the dielectric material. Barrier layers placed between a dielectric material, silicon, and or other materials and the copper interconnect can also serve to promote adhesion of the copper to the other material(s). Delamination (due to poor adherence between materials) is also a difficulty encountered in the fabrication of IC chips that leads to device failure.

Embodiments of the invention provide layers of materials that act as barriers between copper structures and dielectric layers. Advantageously, embodiments of the invention provide layers of material that exhibit a lower resistivity than conventional barrier materials, such as, for example, tantalum (Ta), TaN, titanium (Ti), TiN, and WN. Embodiments of the invention do not require the use of conventional barrier layers, such as, for example, TaN, TiN, and WN. Additionally advantageously, embodiments of the invention enable the use of a thinner and or discontinuous copper seed layer during copper deposition into vias and or trenches which, as feature sizes are scaled to smaller dimensions, enables complete gap fill in the vias and or trenches. Gapfill is especially a problem in high aspect ratio features.

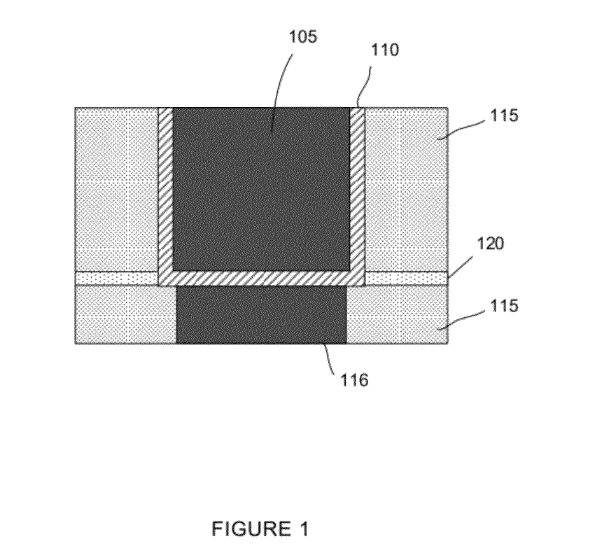

FIG. 1 provides an electrical interconnect structure having a layer of material that is capable of functioning as a barrier layer. In FIG. 1, a metal via 105 (or trench) for an integrated circuit chip is separated from other components of the device by a barrier layer 110 that lines the bottom and sides of the via 105 (or trench). The barrier layer 110 provides a barrier between dielectric layer 115 and the metal via 105 in this embodiment. The dielectric layer 115 can be, for example, what is frequently referred to as an interlayer dielectric layer (ILD). Additionally, in this embodiment, the device additionally features an etch stop layer 120 that resulted from the process used for device fabrication. An etch stop layer may be formed from a dielectric material, such as for example, silicon nitride, silicon oxynitride, and or silicon carbide. Optionally, the metal interconnect of FIG. 1, is in electrical communication with an additional metal interconnect structure 116 (a via). The metal used for interconnects is, for example, copper, aluminum (Al), gold (Au), silver (Ag) and or alloys thereof. In some embodiments of the invention, the metal used for interconnects is copper or the metal is an alloy of copper.

In FIG. 1, the barrier layer 110 is comprised of a thin ruthenium (Ru) layer that has been modified with a second material that has interacted with the Ru layer and or the surface of the dielectric material which is in contact with the Ru layer. A thin Ru layer typically comprises crystalline domains and does not create an adequate barrier to copper migration due to the grain boundaries. The transformation of the Ru layer and or the dielectric material in contact with the Ru layer by the second material creates a barrier layer 110 that blocks copper migration. The second material is, for example, cobalt (Co). The ruthenium layer has an average thickness of between 1 nm and 4 nm. The second material is present in the barrier layer in an amount between 1 and 20 atomic weight percent of the ruthenium.

In additional embodiments, the self-forming barrier layer 110 is a thin metal layer of platinum (Pt), iridium (Ir), palladium (Pd), rhenium (Re), or rhodium (Rh), that has been modified with a second material. The second material has interacted with the first thin layer of material (Pt, Ir, Pd, Re, or Rh) and or the proximate dielectric to form a barrier to copper migration. The second material is Co. The second material is capable of filling the grain boundaries of the thin metal layer and or interacting with the ILD after migration through the thin metal layer to form a barrier, for example. A thermal annealing process can facilitate the mobility and or reactively of the second material. The thin metal layer has an average thickness of between 1 nm and 4 nm. The second material is present in the barrier layer in an amount between 1 and 20 atomic weight percent of the first material.

In embodiments of the invention, the second material (Co) is not necessarily evenly distributed within the thin metal layer. For example, cobalt may preferentially migrate through the metal layer and accumulate on the surfaces of the sides of the trench or via (e.g., on the surface of the dielectric material in which the trench or via is formed).

Advantageously in embodiments of the invention, no tantalum (Ta) or TaN adhesion layer is used with the self-forming barrier layer. The use of a Ta, TaN, Ti, TiN, or WN adhesion (liner) layer increases the resistance of metal interconnect structures as compared to interconnects that do not have a Ta, TaN, Ti, TiN, or WN adhesion (liner) layer. Additionally, as discussed herein, during formation of the interconnect structure, it is possible to use a copper seed layer that does not continuously cover the underlying metal layer. The relaxed requirements for the copper seed layer coverage allow smaller features and features with higher aspect ratios to be formed using metal fill techniques such as electrodeposition (electroplating).

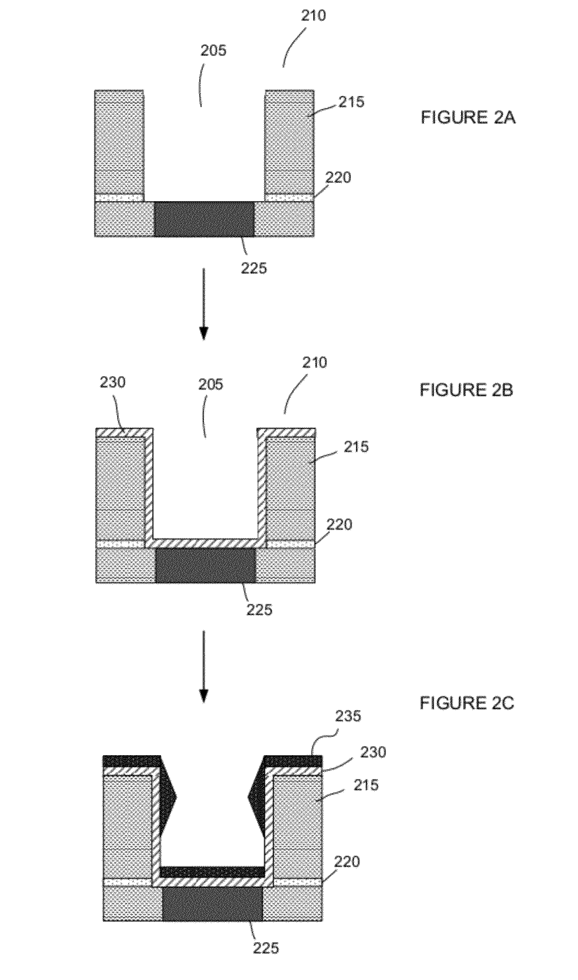

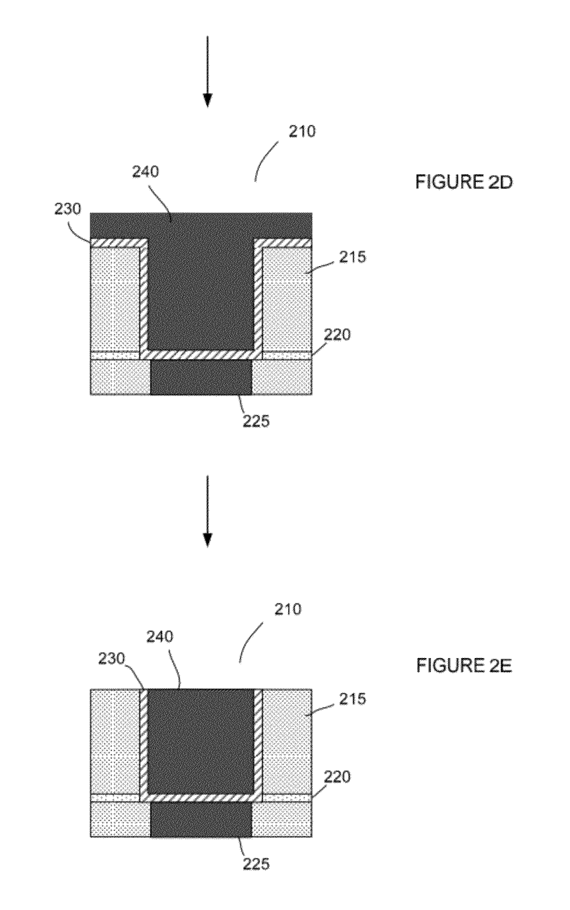

FIGS. 2A-E show a process for creating a barrier layer for metallic interconnect structures. In FIG. 2A a gap structure 205 (e.g., a via or trench or depression) to be filled with a conducting material to create an electrical interconnect is provided in a substrate 210. The gap 205 is typical of the types of vias that are filled during back end metallization processes in which semiconductor devices (e.g., transistors) are interconnected in an integrated circuit chip. The gap structure is, for example, etched into an ILD layer 215 that is comprised of a dielectric material. The dielectric material is, for example, silicon dioxide, low-k dielectrics, and or other dielectric materials. Layer 220 in FIG. 2 is an etch stop layer created during device fabrication. Metallic structure 225 is an electrical device interconnect and is comprised of a conducting metal, such as, for example, copper metal and alloys of copper metal, tungsten metal or alloys of tungsten metal. A thin metallic layer 230 is deposited by atomic layer deposition (ALD), chemical vapor deposition (CVD), or physical vapor deposition (PVD), for example, and the structure of FIG. 2B is obtained. The thin metallic layer 230 is comprised of Ru, Pt, Ir, Pd, Re, or Rh. In embodiments of the invention, the metallic layer 230 is ruthenium. A copper seed layer 235 containing copper and a cobalt dopant is deposited onto the structure of FIG. 2B, and the structure of FIG. 2C is obtained. The dopant is present in the copper seed layer 235 in an amount of 1-20 atomic percentage (at. %) of the seed layer. The seed layer is deposited, for example, by PVD, CVD, electrodeposition, or ALD. Optionally, the seed layer is a thin discontinuous layer. FIG. 2C shows a discontinuous copper seed layer 235. The copper seed layer 235 does not completely cover the metallic layer 230 in the embodiment of FIG. 2C. The copper interconnect 240 material (or other conducting material) is then electrodeposited and the structure is annealed providing the device of FIG. 2D. Annealing is accomplished, for example, by heating the structure to 350-400° C. for two hours. Other temperatures and time periods for annealing are also possible. After annealing, the barrier layer 231 is impermeable to copper migration. The cobalt dopant migration into and or through the metallic layer 230 forms a barrier to copper diffusion. The behavior of the dopant depends in part on the metal selected for the metal layer 230 and the dopant in the copper seed layer 235. In some cases, the dopant crosses the metallic layer 230 and interacts with the dielectric layer 215 to form a barrier layer 231. In other cases the dopant enters the metal layer 230 or a combination of both mechanisms occurs.

A chemical mechanical polish planarizes the top of the copper interconnect 240 to the top of the dielectric layer 215 forming the structure of FIG. 2E. Further interconnect layers (not shown), for example, are then built on structure of FIG. 2E to forming a completed IC device.

In the embodiment of FIGS. 2A-E, a discontinuous seed layer is shown. The seed layer can either be continuous or discontinuous.

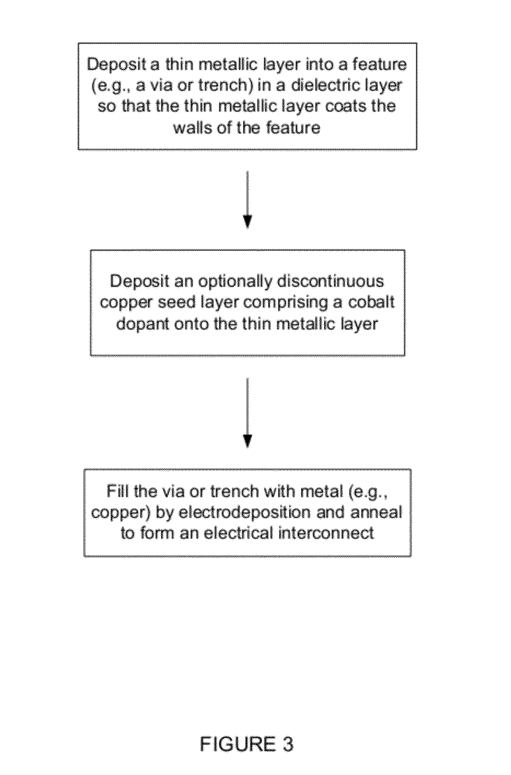

FIG. 3 describes a process for forming barrier layers for back end metallization, e.g., forming copper interconnects for transistor devices for integrated circuit chips. In FIG. 3, a trench or via that is to be filled with a conducting metal to form an electrically conducting interconnect is provided. The trench or via is a depression that is typically formed in a dielectric layer, such as an ILD layer through an etching process used in the semiconductor industry. The walls and bottom of the trench or via (the side(s) of the depression) are coated with a thin metallic layer comprised of Ru, Pt, Ir, Pd, Re, or Rh. In embodiments of the invention, the thin metallic layer comprises Ru and the dopant in the copper seed layer is Co. The thin metallic layer is deposited by ALD, CVD, or PVD, for example. The copper seed layer comprising cobalt is then deposited. The copper seed layer is deposited by ALD, PVD, electrodeposition, or CVD, for example. Advantageously, the copper seed layer can be either continuous or discontinuous. The discontinuous copper seed layer allows a thinner seed layer to be deposited and potentially avoids pinching off features in situations in which small features are to be filled with metal. If a feature becomes pinched off, then an unwanted gap in the metal of the interconnect can form and can lead to device failure. In embodiments of the invention, the copper seed layer has an average thickness of 3 to 10 nm. The trench or via is then filled with metal through an electrodeposition process (electrochemical plating). Annealing the structure provides a electrical interconnect structure having a barrier layer that prevents the migration of metal interconnect material into surrounding materials. Typically, further processing includes chemical mechanical polishing that planarizes the interconnect and the interlayer dielectric material so that both are of essentially equal height.

The cobalt dopant in the seed layer can migrate or diffuse through the copper of the metal interconnect and segregate at the copper-to-etch-stop interface. Segregation of the dopant at this interface leads to improved adhesion between the copper and etch-stop layer. This improved adhesion makes the interconnect structure more resistant to electromigration and can thereby improve device reliability.

In general, an electrodeposition process comprises the deposition of a metal onto a semiconductor substrate from an electrolytic solution that comprises ions of the metal to be deposited. A negative bias is placed on the substrate. The electrolyte solution can be referred to as a plating bath or an electroplating bath. The positive ions of the metal are attracted to the negatively biased substrate. The negatively biased substrate reduces the ions and the metal deposits onto the substrate.

Persons skilled in the relevant art appreciate that modifications and variations are possible throughout the disclosure and combinations and substitutions for various components shown and described. Reference throughout this specification to “one embodiment” or “an embodiment” means that a particular feature, structure, material, or characteristic described in connection with the embodiment is included in at least one embodiment of the invention, but does not necessarily denote that they are present in every embodiment. Furthermore, the particular features, structures, materials, or characteristics may be combined in any suitable manner in one or more embodiments. Various additional layers and or structures may be included and or described features may be omitted in other embodiments.

We claim:

1. A device comprising;
a substrate having a layer of dielectric material on a surface of the substrate, the dielectric material having a depression formed therein, wherein the depression has at least one side and the side of the depression is in contact with a metal layer, wherein the metal of the metal layer is selected from the group consisting of Ru, Pt, Ir, Pd, Re, and Rh, wherein the metal layer additionally comprises Co, wherein the depression is filled with copper, and wherein the metal layer is between the copper and the dielectric material.

2. The device of claim 1 wherein Co is present in the metal layer in an amount from 1 to 20 atomic weight percent of the metal.

3. The device of claim 1 wherein the depression does not comprise a layer comprising Ti, Ta, or W.

4. The device of claim 1 wherein the metal is ruthenium.

5. The device of claim 1 wherein the metal layer is between 1 nm and 4 nm thick.

6. The device of claim 1 wherein the feature is a trench or via.

7. The device of claim 1 wherein the Co is not evenly distributed throughout the layer of metal.

8. A method comprising,
providing a substrate having a surface, the surface having a depression in the substrate surface wherein the depression has at least one surface,
depositing a metal layer, the metal of the metal layer being selected from the group consisting of Ru, Pt, Ir, Pd, Re, and Rh, onto the at least one surface of the depression,
depositing a copper seed layer wherein the copper seed layer comprises a cobalt dopant, onto the metal layer, and
depositing copper into the depression.

9. The method of claim 8 wherein the substrate surface comprises a dielectric material and the depression is formed in the dielectric material.

10. The method of claim 8 wherein the copper seed layer is a discontinuous layer.

11. The method of claim 1 wherein the cobalt dopant is present in the copper seed layer in an amount from 1 to 20 atomic weight percent.

12. The method of claim 8 wherein the copper is deposited into the depression by electrodeposition.

13. The method of claim 8 where annealing occurs after copper seed layer deposition or after deposition of the copper interconnect layer.

14. The method of claim 1 wherein the metal layer is Ru.

15. The method of claim 8 wherein a copper-filled depression resulting from the method of claim 1 does not have a layer comprising Ti, Ta, or W.

16. The method of claim 8 wherein the depression is a trench or a via.
